(19) United States
(12) Patent Application Publication
(10) Pub. No.: US 2012/0174567 A1
(43) Pub. Date: Jul. 12, 2012

(54) THERMOELECTRIC DEVICE WITH TUBE BUNDLES, METHOD FOR OPERATING A THERMOELECTRIC DEVICE AND MOTOR VEHICLE HAVING A THERMOELECTRIC DEVICE

(75) Inventors: SIGRID LIMBECK, MUCH (DE); ROLF BRÜCK, BERGISCH GLADBACH (DE); ANDREAS EDER, MUENCHEN (DE)

(73) Assignees: BAYERISCHE MOTOREN WERKE AKTIENGESELLSCHAFT, MUENCHEN (DE); EMITEC GESELLSCHAFT FUR EMISSIONSTECHNOLOGIE MBH, LOHMAR (DE)

(21) Appl. No.: 13/351,363

(22) Filed: Jan. 17, 2012

Related U.S. Application Data
(63) Continuation of application No. PCT/EP2010/060258, filed on Jul. 15, 2010.

(30) Foreign Application Priority Data
Jul. 17, 2009 (DE) 10 2009 033 613.3

(51) Int. Cl. F01N 5/02; H01L 35/32; H01L 35/30

(52) U.S. Cl. 60/320; 136/210

(57) ABSTRACT

A thermoelectric device or thermoelectric generator (TEG) includes at least one exhaust line having an inlet and an outlet. At least one first tube bundle is a thermoelectric generator module and has tubes with outer surfaces forming the exhaust line in the thermoelectric generator module. At least one further tube bundle is a heat exchanger and has tubes with inner surfaces forming the exhaust line in the heat exchanger. A method for operating a thermoelectric device and a motor vehicle having a thermoelectric device are also provided.

### CROSS-REFERENCE TO RELATED APPLICATION

This is a continuation, under 35 U.S.C. §120, of copending International Application No. PCT/EP2010/060258, filed Jul. 15, 2010, which designated the United States; this application also claims the priority, under 35 U.S.C. §119, of German Patent Application DE 10 2009 033 613.3, filed Jul. 17, 2009; the prior applications are herewith incorporated by reference in their entirety.

### BACKGROUND OF THE INVENTION

### Field of the Invention

The present invention relates to a thermoelectric device having at least one exhaust line with an inlet and an outlet for the exhaust gas. The thermoelectric device serves, in particular, for producing electrical energy from the exhaust gas of an internal combustion engine. Thermoelectric devices of that type are also known as thermoelectric generators (TEG). The invention also relates to a method for operating a thermoelectric device and a motor vehicle having a thermoelectric device.

The exhaust gas from the internal combustion engine of a motor vehicle has thermal energy which can be converted through the use of such a thermoelectric device into electrical energy, for example in order to charge an energy storage device and/or supply an electrical consumer directly with the required energy. The motor vehicle is thereby operated with greater energy efficiency, and a greater amount of energy is available for the operation of the motor vehicle.

A thermoelectric device of that type has at least a plurality of thermoelectric converter elements. Thermoelectric materials which are used for that purpose are of such a type that they can convert the effectively thermal energy into electrical energy (The Seebeck effect) and vice versa (The Peltier effect). The “Seebeck effect” is based on the phenomenon of the conversion of heat energy into electrical energy and is used for generating thermoelectric energy. The “Peltier effect” is the reverse of the “Seebeck effect” and is a phenomenon associated with heat adsorption and its cause is related to a flow of current through different materials. Both effects are known, and therefore a more detailed description is not necessary at this juncture.

Thermoelectric converter elements of that type preferably have a multiplicity of thermoelectric elements which are positioned between a so-called hot side (at which high temperatures prevail during operation) and a so-called cold side (at which relatively low temperatures prevail during operation). Thermoelectric elements include at least two semiconductor elements (p-doped and n-doped) which are alternately provided, on their top side and bottom side (respectively facing the hot side and cold side), with electrically conductive bridges. Ceramic plates or ceramic coatings and/or similar materials serve to isolate the metal bridges and are therefore preferably disposed between the metal bridges. If a temperature gradient is provided on the two sides of the semiconductor elements, a voltage potential is formed. In that case, heat is absorbed on the hot side of the first semiconductor element, so that the electrons on one side pass to the energetically higher conduction band of the following semiconductor element. On the cold side, the electrons can then release energy and pass to the following semiconductor element with a lower energy level. Therefore, a flow of electrical current can be generated, given a corresponding temperature gradient between the hot side and the cold side.

A potential application for a thermoelectric device of that type is an exhaust-gas recirculation (AGR or EGR) system in a motor vehicle. In that case, a part of the exhaust gas produced in the internal combustion engine is firstly conducted to the conventional exhaust system, but is then branched off and supplied to the internal combustion engine again. With regard to the effectiveness of the internal combustion engine and the reduction of pollutants in the exhaust gas, it is conventional to cool the recirculated exhaust gas. It is therefore conventional for heat exchangers to be provided in the region of the exhaust-gas recirculation system, through the use of which heat exchangers the hot exhaust gas is cooled. In that case, however, particularly high demands must be placed on a thermoelectric device of that type because there is usually only a very small amount of installation space available. That results in the difficulty that a particularly good heat transfer must be realized for the thermoelectric converter elements, while at the same time, however, attaining the desired cooling action.

### SUMMARY OF THE INVENTION

It is accordingly an object of the invention to provide a thermoelectric device with tube bundles, a method for operating a thermoelectric device and a motor vehicle having a thermoelectric device, which overcome the hereinafore-mentioned disadvantages and at least partially solve the highlighted problems of the heretofore-known devices, methods and vehicles of this general type. In particular, it is sought to specify a thermoelectric device which has a high level of efficiency and which, in particular, also ensures adequate cooling of re-circulated exhaust gas. It is also sought to specify a particularly suitable operating method and motor vehicle for this purpose.

With the foregoing and other objects in view there is provided, in accordance with the invention, a thermoelectric device, comprising at least one exhaust line having an inlet and an outlet, at least one first tube bundle being a thermoelectric generator module, the at least one first tube bundle having tubes with outer surfaces forming the exhaust line in the thermoelectric generator module, and at least one further tube bundle being a heat exchanger, the at least one further tube bundle having tubes with inner surfaces forming the exhaust line in the heat exchanger.

Accordingly, in other words, the thermoelectric device is distinguished, in particular, by the guidance of the exhaust gas past the tube bundle or through the tube bundle. It is preferable in this case for the thermoelectric device to have a plurality of modules which are, for example, also connected to one another by corresponding fastening pieces. The exhaust line can therefore firstly be formed, in one module, by an outer housing and the outer surfaces of the tubes, whereas the exhaust line is formed, in another module, only by the inner surfaces of the tubes. It is therefore possible, in particular, for the number of exhaust lines or the construction thereof to differ in the different modules.

The first tube bundle, which is formed, in particular, following the inlet of the exhaust line into the thermoelectric device, is a thermoelectric generator module. In other words, this means that the first tube bundle is formed with the semiconductor elements explained in the introduction, in order to generate electrical energy. In this case, the exhaust gas is conducted along the outside of the first tube bundle, so as to permit a good transfer of heat from the hot exhaust gas to the tubes, that is to say, in particular, a uniform inflow of the exhaust gas into the first tube bundle is realized. Measures for enhanced heat transfer may also be implemented in this case, if appropriate. A good introduction of heat into the tubes of the first tube bundle is realized as a result of the flow of the hot exhaust gas around and past the tubes over a large area thereof. In a thermoelectric generator module, a coolant flows through the inside of the tubes, in such a way that during operation, the temperature gradient, which is required for the “Seebeck effect,” between the outer surface of the tubes and the inner surface of the tubes, is particularly pronounced. The semiconductor elements are disposed between the outer surfaces of the tubes and the inner surfaces of the tubes. It is therefore clear and self-evident that the first tube bundle also performs the function of a heat exchanger, but simultaneously or predominantly also performs thermoelectric functions.

After the exhaust gas has flowed along the exhaust line firstly over the first tube bundle, it is finally supplied to a further tube bundle which forms (only) a heat exchanger. In this case, the exhaust line is formed by the inner surfaces of the tubes, that is to say in other words that the exhaust gas is now conducted through the tubes themselves. In this case, the coolant flows over or around the tubes of the heat exchanger, in such a way that particularly effective cooling of the exhaust gas is possible in this case because the coolant can dissipate the thermal energy over the large outer surfaces of the tubes.

Merely for the sake of completeness, it is pointed out herein that the expressions “tube bundle” and “tubes” need not imperatively refer to cylindrical tubes. In particular, any desired flow cross section may be realized, and the tubes may also in part be formed in a common wall. A “tube bundle” is to be understood, in particular, to mean a collection of channels which has an outer channel wall and an inner channel wall, wherein the outer channel wall is larger than the inner channel wall. Such tube bundles may accordingly also be realized as a honeycomb structure, plug-type configuration and the like.

In any case, as a result of the flow of the exhaust gas around the thermoelectric generator module on one hand and the flow of the exhaust gas through the heat exchanger on the other hand, particularly good heat transfer either from the exhaust gas to the thermoelectric converter elements or from the coolant to the exhaust gas is realized, in such a way that both modules operate particularly effectively and can therefore be formed with a relatively small volume. This meets the requirement for realizing a space-saving thermoelectric device.

In accordance with another feature of the invention, at least two tube bundles are formed as a thermoelectric generator module and a single tube bundle at the outlet is formed as a heat exchanger. Accordingly, downstream of the inlet into the thermoelectric device, the exhaust gas firstly flows over a first tube bundle in the form of a thermoelectric generator module, then a second tube bundle in the form of a thermoelectric generator module, and finally a third tube bundle in the form of a heat exchanger, before the exhaust gas finally exits the thermoelectric device through the outlet. Such a thermoelectric device makes it possible for the two thermoelectric generator modules to be adapted separately, or independently of one another, to the different exhaust-gas temperatures downstream of the inlet into the thermoelectric device, in which case, for example different tube bundles, semiconductor elements, etc. may be used. Through the use of the downstream heat exchanger, the exhaust gas is then brought very quickly to the low temperature required for the exhaust-gas recirculation to the internal combustion engine.

In accordance with a further feature of the invention, it is considered to be advantageous for a common coolant circuit for the tube bundles to be provided, in which case a connection of the coolant circuit is connected to the tube bundle which forms a heat exchanger, and an outflow of the coolant circuit is connected to at least one tube bundle which forms a thermoelectric generator module. The coolant circuit may also be part of or connected to the engine cooling system. With regard to the thermoelectric device as a whole, it is preferable for a form of countercurrent principle to be realized, in such a way that the cold coolant is supplied in the region of the outlet and is discharged again in the region of the inlet. For the individual modules, it is provided in particular that cooling takes place in this case according to the countercurrent principle, that is to say the exhaust gas and coolant flow perpendicular to one another within the modules. Specifically if a plurality of tube bundles are used as a thermoelectric generator module, it is possible for coolant to be supplied to all of the tube bundles equally, that is to say in parallel, which coolant is then if appropriate also extracted again equally, that is to say in parallel. It is basically also possible for at least one bypass line and/or a control device to be provided in order to separate at least one of the tube bundles from the coolant circuit, wherein this is done, for example, for the heat exchanger if it is detected that additional cooling at the outlet of the thermoelectric device is no longer required. Water is used, in particular, as a coolant.

In accordance with an added feature of the invention, it has been found to be advantageous if, in the thermoelectric device, at least a number of the tubes or an inner diameter of the tubes of a tube bundle which forms a thermoelectric generator module is smaller than the number or the inner diameter of the tubes of a tube bundle which forms a heat exchanger. That is to say, in other words, that the number of tubes and/or the inner diameter of the tubes are/is smaller in the thermoelectric generator module than in the heat exchanger. This configuration of the tubes, too, promotes the different heat transfer effects firstly from the coolant to the exhaust gas and also from the exhaust gas to the thermoelectric converter elements.

The number of tubes in the thermoelectric generator module is, for example, between 5 and 30, in particular between 12 and 24. An inner diameter in the range from 5 to 15 mm [millimeters] is likewise preferable in this case.

By contrast, a configuration of the heat exchanger has proven to be advantageous in which the number of tubes lies in the range from 10 to 60 (in particular is greater than in the thermoelectric generator module, for example the heat exchanger particularly preferably includes at least twice as many or even at least 30 tubes), wherein the inner diameter of the tubes is preferably 8 to 20 mm.

Reducing the inner diameter of the tubes in the thermoelectric generator module advantageously increases the heat transfer coefficient a [alpha] of the heat transfer taking place at the inside. Reducing the number of tubes while maintaining the same tube diameter also increases the heat transfer coefficient a to the inside. In this case, the heat transfer coefficient a describes the capability of the gas or the liquid to dissipate energy from the surface of the tube or to release energy to the surface. The heat transfer coefficient a is dependent, inter alia, on the specific heat capacity, the density and the coefficient of thermal conductivity of the heat-dissipating medium and of the heat-delivering medium. The coefficient of thermal conduction is calculated usually through the use of the temperature difference of the media involved. The heat transfer coefficient a, in contrast to the thermal conductivity, is not a material constant but rather, in the case of an environment, is highly dependent on the flow speed or the type of flow (laminar or turbulent) of the fluid coming into contact with the tubes. The above values therefore relate, in particular, to devices such as are intended for use in motor vehicles, wherein an undesirably high pressure loss of the exhaust gas flowing through the device is likewise avoided.

In accordance with an additional feature of the thermoelectric device of the invention, the tubes of the tube bundles which form a thermoelectric generator module are aligned differently with respect to a flow direction of the exhaust gas than the tubes of the tube bundle which form a heat exchanger. This preferably yields a configuration of the tube bundles in which the flow direction of the exhaust gas through the thermoelectric device remains uniform. While it is the case in the portions with the thermoelectric generator modules that the tubes are aligned perpendicular to the flow direction and, there, the exhaust gas is conducted over the outer surfaces of the tubes and between the tubes, it is the case in the portion with the heat exchanger that the exhaust gas enters into the tubes of the tube bundles, which are then aligned parallel to the flow direction of the exhaust gas. It is thereby possible, in particular, for the pressure loss for the exhaust gas as it flows through the thermoelectric device to be kept low.

With the objects of the invention in view, there is also provided a method for operating a thermoelectric device. The method comprises providing the thermoelectric device according to the invention, initially conducting hot exhaust gas past the outer surfaces of the plurality of first tube bundles forming the generator module, and subsequently conducting the hot exhaust gas along the inner surfaces of the tubes of the further tube bundle forming the heat exchanger.

Therefore, the exhaust gas firstly flows around the coolant-conducting tubes in the generator modules, and subsequently, the coolant flows around the tubes through which the exhaust gas is conducted. This flow behavior leads to particularly good heat transfer and therefore increases the efficiency as a generator module and heat exchanger.

In accordance with another mode of the method of the invention, it is considered to be particularly advantageous for a coolant flow through a tube bundle formed as a heat exchanger to be varied. The coolant flow through the heat exchanger can consequently also be controlled, in particular as a function of the recirculation rate of the recirculated exhaust gas, the temperature of the exhaust gas, the load state of the engine, the temperature of the engine, etc. If it is detected that the cooling of the exhaust gas through the use of the generator modules is already adequate, the coolant flow through the heat exchanger may also be completely shut off.

With the objects of the invention in view, there is concomitantly provided a motor vehicle, comprising an internal combustion engine and an exhaust system associated with the internal combustion engine. The exhaust system has an exhaust-gas recirculation system for recirculating exhaust gas to the internal combustion engine, and the exhaust-gas recirculation system includes a thermoelectric device according to the invention described herein.

Other features which are considered as characteristic for the invention are set forth in the appended claims, noting that the features specified individually in the claims may be combined with one another in any desired technologically expedient manner and form further embodiments of the invention.

Although the invention is illustrated and described herein as embodied in a thermoelectric device with tube bundles, a method for operating a thermoelectric device and a motor vehicle having a thermoelectric device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, perspective view of a structural variant of a thermoelectric device;

FIG. 2 is an enlarged, longitudinal-sectional view of a structural variant of a tube of a thermoelectric generator module; and

FIG. 3 is a plan view of a motor vehicle having a thermoelectric device in an exhaust-gas recirculation system.

### DETAILED DESCRIPTION OF THE INVENTION

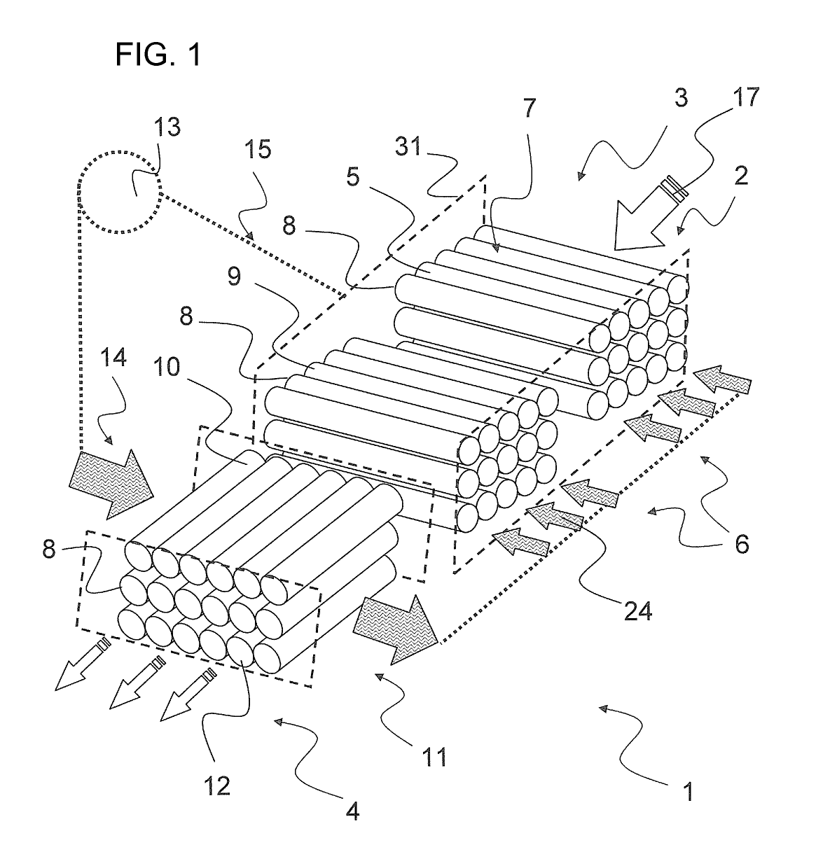

Referring now in detail to the figures of the drawing for explaining the invention and the technical field in more detail by showing particularly preferred structural variants to which the invention is not restricted, and first, particularly, to FIG. 1 thereof, there is seen a diagrammatic and partially perspective illustration of a structural variant of a thermoelectric device 1 according to the invention. An exhaust line 2, which is likewise diagrammatically indicated therein, extends through the thermoelectric device 1 and has an inlet 3 formed at the top right and an outlet 4 formed at the bottom left. A plurality of tube bundles is disposed in the exhaust line 2, in a housing 31. The housing 31 also delimits the exhaust line 2 at least in the region of a first tube bundle 5. It is also pointed out that the housing 31 is preferably also formed with at least one compensation element for compensating thermal expansions of the tubes and connections.

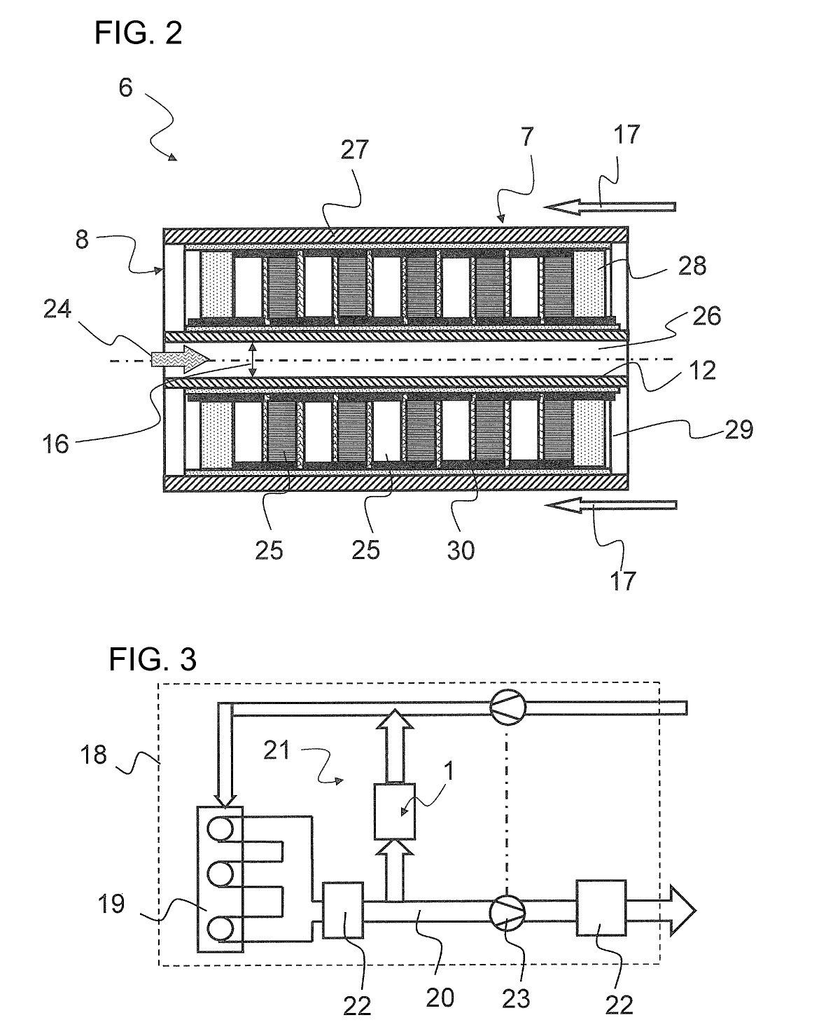

The exhaust gas flows through the inlet 3 into the thermoelectric device 1 in a flow direction 17. In this case, the exhaust gas impinges on the first tube bundle 5 which has a multiplicity of tubes 8 that are disposed transversely or perpendicularly with respect to the flow direction 17 of the exhaust gas. The exhaust gas is therefore conducted over outer surfaces 7 of the tubes 8 and a uniform flow over or past or between the tubes 8 in the first tube bundle 5 is realized through the use of a correspondingly suitable incident flow. After the exhaust gas has flowed through the first tube bundle 5, it flows through a following second tube bundle 9 which likewise has a multiplicity of tubes 8. The first tube bundle 5 and the second tube bundle 9 have substantially the same alignment with respect to the flow direction 17, and the exhaust gas likewise flows uniformly around them. The number of tubes 8 or the position of the tubes with respect to the flow direction 17 and/or the construction of the tubes may differ between the first tube bundle 5 and the second tube bundle 9, but they are formed in any case as thermoelectric generator modules 6. That is to say, in other words, that energy is obtained through the use of the two generator modules 6 and suitable electrical terminals lead away from the housing 31. The tubes 8 therefore have corresponding semiconductor elements, as will be explained in more detail below in conjunction with FIG. 2.

After the exhaust gas has exited the second tube bundle 9, it impinges on a third tube bundle 10, which again has a multiplicity of tubes 8. In this case, the tubes 8 are aligned parallel to the flow direction 17 of the exhaust gas, in such a way that the exhaust gas can (only) enter into the tubes 8, and finally exits on the opposite side close to the outlet 4 of the thermoelectric device 1. In this case, the exhaust gas is conducted internally over inner surfaces 12 of the tubes 8.

FIG. 1 also shows how an advantageous coolant circuit 13 may be constructed. In this case, the coolant flows through a connection 14 and firstly over the third tube bundle 10. Therefore, only an exchange of heat is intended to take place by using a heat exchanger 11, with the aim of cooling the exhaust gas, which is conducted through at the inside, to a desired temperature. After the coolant has flowed through the heat exchanger 11, the coolant is diverted and then conducted internally through all of the tubes 8 of the first tube bundle 5 and of the second tube bundle 9 in parallel, so as to follow a delivery direction 24. In this case, too, the coolant is merged again on the opposite side and re-circulated through an outflow 15, before the coolant itself is brought to a lower temperature, for example through the use of a cooler.

FIG. 2 shows a possible construction of a tube 8 for a thermoelectric generator module 6. As already explained above, the tube 8 forms an outer surface 7 along which the exhaust gas is conducted in the flow direction 17. The outer surface 7 is formed in this case by an outer casing 27. The tube 8 also has, concentrically with respect to the outer casing 27, an inner casing 26 which forms the inner surface 12 of the tube. The coolant is conducted in the delivery direction 24 through the inner casing 26 which has an inner diameter 16. Due to this construction, an annular intermediate space 29 is formed in which semiconductor elements 25 are disposed. An end side of the intermediate space 29 is provided, for example, with a closure 28, such as for example a sealing compound or the like, in order to prevent an infiltration of exhaust gas and/or coolant. The semiconductor elements 25 (with n-doped and p-doped semiconductor elements 25 being denoted by different hatching therein) are disposed on a thin electrical insulation layer which permits good heat transfer, both from the outer casing 27 to the semiconductor elements 25 as well as from the inner casing 26 to the semiconductor elements 25. A particularly large temperature gradient can thus be set toward the inside and toward the outside with respect to the semiconductor elements 25. As indicated therein, the different semiconductor elements 25 are connected in pairs in an opposing manner as defined by electrical contacts 30. During operation, a flow of current is thus generated due to the temperature gradient, so that the energy obtained can be drawn off from the thermoelectric device 1 and supplied to desired consumers and/or accumulators.

FIG. 3 shows, again diagrammatically, the basic construction of a motor vehicle 18 having an internal combustion engine 19 in which exhaust gas is produced. The exhaust gas is supplied to an exhaust system 20 which has, for example, a plurality of catalytic converters 22 for eliminating pollutants, particles and the like. The motor vehicle 18 which is illustrated in this case has an exhaust-gas turbocharger 23. An exhaust-gas recirculation system 21, which is provided between the internal combustion engine 19 and the turbocharger 23, has a thermoelectric device 1 integrated therein. This is the particularly preferred installation location for the thermoelectric device 1 described herein because, in this case, a compact and space-saving integration of the thermoelectric device 1 has been made possible, in particular due to the high effectiveness of the thermoelectric device 1.

1. A thermoelectric device, comprising:
at least one exhaust line having an inlet and an outlet;
at least one first tube bundle being a thermoelectric generator module, said at least one first tube bundle having tubes with outer surfaces forming said exhaust line in said thermoelectric generator module; and
at least one further tube bundle being a heat exchanger, said at least one further tube bundle having tubes with inner surfaces forming said exhaust line in said heat exchanger.

2. The thermoelectric device according to claim 1, wherein said at least one first tube bundle includes at least two tube bundles each forming a respective thermoelectric generator module, and said at least one further tube bundle is a single tube bundle forming said heat exchanger at said outlet.

3. The thermoelectric device according to claim 1, which further comprises a common coolant circuit for said tube bundles, said coolant circuit having a connection connected to said at least one further tube bundle forming said heat exchanger, and said coolant circuit having an outflow connected to said at least one first tube bundle forming said thermoelectric generator module.

4. The thermoelectric device according to claim 1, wherein at least a number of said tubes of said at least one first tube bundle forming said thermoelectric generator module is less than a number of tubes of said at least one further tube bundle forming said heat exchanger.

5. The thermoelectric device according to claim 1, wherein at least an inner diameter of said tubes of said at least one first tube bundle forming said thermoelectric generator module is smaller than an inner diameter of said tubes of said at least one further tube bundle forming said heat exchanger.

6. The thermoelectric device according to claim 1, wherein said tubes of said at least one first tube bundle forming said thermoelectric generator module are aligned differently, relative to a flow direction of the exhaust gas, than said tubes of said at least one further tube bundle forming said heat exchanger.

7. The thermoelectric device according to claim 1, wherein at least some of said tubes have an outer casing and an inner casing defining an intermediate space therebetween, and a plurality of alternately disposed n-doped and p-doped semiconductor elements in said intermediate space for generating electrical energy.

8. A method for operating a thermoelectric device, the method comprising the following steps:
providing at least one exhaust line having an inlet and an outlet;
providing a plurality of first tube bundles being thermoelectric generator modules, the plurality of first tube bundles having tubes with outer surfaces forming the exhaust line in the thermoelectric generator modules;
providing a further tube bundle being a heat exchanger, the further tube bundle having tubes with inner surfaces forming the exhaust line in the heat exchanger;
initially conducting hot exhaust gas past the outer surfaces of the plurality of first tube bundles forming the generator module; and
subsequently conducting the hot exhaust gas along the inner surfaces of the tubes of the further tube bundle forming the heat exchanger.

9. The method according to claim 8, which further comprises varying a coolant flow through the further tube bundle forming the heat exchanger.

10. A motor vehicle, comprising:
an internal combustion engine;
an exhaust system associated with said internal combustion engine;
said exhaust system having an exhaust-gas recirculation system for recirculating exhaust gas to said internal combustion engine; and
said exhaust-gas recirculation system including a thermoelectric device according to claim 1.
